(19) United States
(12) Patent Application Publication
(10) Pub. No.: US 2008/0272712 A1
(43) Pub. Date: Nov. 6, 2008

(54) Variable Color Light Emitting Device and Method for Controlling the Same

(75) Inventors: Cornelis Jojakim Jalink, Eindhoven (NL); Guido Henri Maria Van Tartwijk, Shanghai (CN); Christoph Gerard August Hoelen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/067,332

(22) PCT Filed: Sep. 12, 2006
(86) PCT No.: PCT/IB2006/053237

§ 371 Date: Mar. 19, 2008

(30) Foreign Application Priority Data
Sep. 19, 2005 (EP) 05108576.9

(51) Int. Cl. H05B 41/36; H01L 33/00; H05B 37/02

(52) U.S. Cl. 315/291; 257/79; 250/201.1

(57) ABSTRACT

The present invention relates to a variable color light emitting device (10) comprising a light emitting diode (12) for emitting light, which diode in turn comprises a plurality of electrically conducting layers (14, 16, 18), at least one of which being such that lateral current spreading in the diode is limited to form at least two independently electrically addressable segments (36), for allowing illumination of an optional number of the segments. At least one of the number of segments is provided with a wavelength converter (34) adapted to convert at least part of the light emitted from its associated segment to generate light of a certain primary color. The invention also relates to systems incorporating at least one such light emitting device and a method for controlling such a light emitting device.

The present invention relates to a variable color light emitting device, as well as systems incorporating at least one such light emitting device and a method for controlling such a light emitting device.

It is well known that combining the projected light of one color with the projected light of another color will result in the creation of a third color. It is also well known that the three most commonly used primary colors (namely red, green and blue) can be combined in different proportions to generate almost any color in the visible spectrum.

These understandings are widely utilized in various variable color lighting systems, wherein different colors can be generated by mixing primary colors in predetermined ways. Such systems are used for example for illumination purposes. One such system is disclosed in the patent document U.S. Pat. No. 6,016,038. In, U.S. Pat. No. 6,016,038, as well as in other known variable color lighting systems and multi-color light emitting devices, one individual light source, namely one light emitting diode (LED), is used to create each primary color. That is, the system comprises a plurality of light sources each providing a single color. Another example is disclosed in the patent document U.S. Pat. No. 5,952,681, wherein a multi-color LED comprises three individual LED chips arranged on a substrate, which LED in combination with wavelength converting layers can emit red, green, and blue light.

However, a disadvantage of the existing systems and devices is the difficulty in mixing the primary colors from the individual light sources. As the light sources are spatially separated (the light sources are usually placed beside one another and separated laterally, as in for instance U.S. Pat. No. 5,952,681), all kinds of optical solutions are applied to mix the light and guarantee homogenous color mixing throughout the emitted beam. For example beam splitter/combiners, dichroic mirrors, diffusion plates, etc. are used. Such optical solutions can be expensive and/or decrease the luminous efficacy, etc., especially as the individual light sources may be misaligned in relation to each other. The light sources can be rotated or tiled, which particularly in so called phosphor converted LEDs will cause color and intensity inhomogenities.

Moreover, when using several separate light sources each generating a primary color in a color lighting system, one has to consider binning issues in order to achieve a homogenous color lighting system. That is, one must make sure that the separate light sources are matched when it comes to brightness, wavelength of emitted radiation, etc.

Another drawback with using several separate light sources is that they may occupy an unnecessarily large amount of space. For example, in U.S. Pat. No. 5,952,681, there is a relatively large non-radiative area due to the repetitive use of N-type electrodes for each chip.

It is an object of the present invention to alleviate these problems, and to provide an improved variable color light emitting device.

This and other objects that will be evident from the following description are achieved by means of a variable color light emitting device, as well as systems incorporating at least one such light emitting device and a method for controlling such a light emitting device, according to the appended claims.

According to an aspect of the invention, there is provided a variable color light emitting device comprising a light emitting diode for emitting light, which diode comprises a plurality of electrically conducting layers, at least one of which being such that lateral current spreading in the diode is limited in order to form at least two independently electrically addressable segments, for allowing rumination of an optional number of the segments, wherein at least one of the number of segments is provided with a wavelength converter adapted to convert at least part of the light emitted from its associated segment to generate light of a certain primary color.

The invention is based on the understanding that the diode can be divided into several independently or individually addressable segments or parts by confining the current spreading in the diode. The diode, in combination with appropriate wavelength converters, can be used to variably emit a plurality of different colors, which colors in turn can be combined or mixed to a desired overall output color. One segment, several segments, or all segments can be ruminating at any given time, and the intensity of the rumination of each segment can preferably be varied, depending on the desired overall output color and power. Each wavelength converter is spatially and geometrically matched with its associated segment.

Having at least two segments, one of which being provided with a wavelength converter, means that the light emitting device is capable of emitting at least two primary colors (which can be combined or mixed to a third color). Assume for example that the light emitting device comprise two segments. In this case, each of the two segments can be provided with a different wavelength converter, whereby two different primary colors can be generated. Alternatively, one segment is provided with a wavelength converter, which generates a certain primary color, while the other (primary) color is the color of the light emitted directly from the other segment.

An advantage with the variable color light emitting device according to the invention is that the primary colors originate from the same source (in most applications virtually approaching a point source), thereby reducing the need for expensive or ineffective optical systems for mixing the emitted primary colors. Such a variable color light emitting device also occupies little space, and the radiative area of the light emitting device is increased considerably. Moreover, when using a light emitting device having one diode, one is relieved from most binning issues mentioned above.

The diode preferably comprises a single continuous active layer interposed between an N-type layer and a P-type layer. Further, the at least two independently electrically addressable segments preferably share the same single continuous active layer, i.e. different parts of the single continuous active layer belong to different segments.

Further, the diode is preferably monolithically grown. The difference should be noted between a single (monolithically grown) diode having several individually addressable segments according to the invention, and prior art devices comprising an ensemble of monolith diodes mounted to a substrate. The former is a construction of a single entity, whereas the latter is a construction of individual entities.

The current confinement discussed above can be achieved in various ways. In one embodiment, the diode comprises at least one high-resistance region, the extension of which defines the segments. Resistance here refers to opposition to the flow of electric current. Thus, the at least one high-resistance region limits the current spreading in the diode. The at least one high-resistance region can for example be achieved by etching separation or blocking channels in the diode. Mechanical abrasion or laser ablation could also be used. Alternatively, one can electrically passivate regions of the diode by implementing passivating dopants in the host material of the diode.

The at least one high-resistance region is preferably incorporated in at least one of the electrically conducting layers of the diode. It can for example be incorporated in the P-type layer. The high-resistance region(s) can have such an extension in the P-type layer that the P-type layer is continuous or discontinuous. Here, the active layer and the N-type layer are electrically unstructured, and the current spreading is determined by the high-resistance region(s) in the P-type layer. The high resistance region(s) could alternatively in a similar way be incorporated in the N-type layer, in which case the active layer and the P-type layer are electrically unstructured.

Alternatively, the at least one high-resistance region can be incorporated in the active layer and at least one of the P-type layer and N-type layer. In this case, the at least one high-resistance region should have a lateral/horizontal extension in the active layer such that the active layer remains continuous, i.e. formed in one piece. The at least one high-resistance region can for example be incorporated in both the P-type layer and the active layer (in which case the N-type layer is electrically unstructured, and the current spreading is determined by the high-resistance region(s) in the two structured layers (i.e. the P-type layer and the active layer), or in all conducting layers (i.e. the P-type layer, the active layer, and the N-type layer)).

Preferably, the high resistance regions have the same horizontal or lateral extension in all the layers in which they are incorporated. This can be achieved using a single mask and a single etching step. It is however possible for the high resistance region(s) in one layer to have a different lateral extension or pattern than another layer. This can be achieved using two masks and two etching steps. The two masks may overlap for part of the pattern, one may be an extension of the first, they may be completely different, etc. This allows for a structured but continuous active layer together with a structured and discontinuous P-type layer.

In case the at least one high-resistance region is incorporated in all conducting layers, the structured active layer and the N-type layer should be continuous, while the structured P-type layer can be continuous or discontinuous. Preferably, the at least one high-resistance region extends vertically through part of the N-type layer's cross-section, in order to avoid that the current flow between a segment and the N-type contact is completely obstructed.

In another embodiment, electrical contacts are connected to the P-type layer and the thickness of the P-type layer is such that lateral current spreading in the diode is limited, whereby the segments are defined by the contact area between the contacts and the P-type layer. Thus, the lateral current spreading in the diode is determined by the thickness of the P-type layer and the size and extent of the electrical contacts connected to the P-type layer.

In yet another embodiment, the at least one wavelength converter is in mechanical and optical contact with the diode. This offers the advantage of reducing the amount of radiation from a segment that is spread to the wavelength converters associated with neighboring segments due to refraction and/or reflection at the interfaces between the various components of the diode.

The light emitting device according to the invention can for example comprise at least one wavelength converter adapted to convert at least part of the incoming light from the active layer into red light, at least one wavelength converter adapted to convert at least part of the incoming light into green light, and at least one wavelength converter adapted to convert at least part of the incoming light into blue light, thus forming an RGB light emitting device. In case the active layer of the diode emits blue light, the blue wavelength converter(s) can be omitted. Alternatively, the light emitting device according to the invention can for example comprise at least one wavelength converter adapted to convert at least part of the incoming blue light from the active layer into yellow light, in order to produce white light. It should however be noted that various other color combinations are possible.

According to another aspect of the invention, there is provided a variable color lighting system comprising at least one variable color light emitting device according to the above description, and at least one controller, each controller being coupled to at least one variable color light emitting device and capable of varying the intensity of the lumination of each segment of its associated light emitting device(s) in order to generate a desired mixed color in response to an input control signal.

According to yet another aspect of the invention, there is provided a variable color lighting system network comprising a plurality of variable color light emitting systems according to the above description, the controllers of which systems being coupled together in a network, and a central processor for supplying input control signals, based on instructions from a user interface, to the controllers via said network.

According to yet another aspect of the invention, there is provided a variable color light emitting device assembly, comprising a plurality of variable color light emitting devices according to the above description, wherein the segment responsible of emitting light of a certain primary color in combination with any wavelength converter in one of the light emitting devices is connected in series with the segment or segments responsible of emitting light of the same primary color in at least one of the other light emitting devices.

According to yet another aspect of the invention, there is provided a controller for a variable color lighting system, the system comprising at least one variable color light emitting device according to the above description, wherein the controller is coupled to at least one of the variable color light emitting devices and adapted to vary the intensity of the rumination of each segment of its associated light emitting device(s) in order to generate a desired mixed color in response to an input control signal.

According to yet another embodiment of the invention, there is provided a method for controlling a variable color light emitting device according the above description, the method comprising varying the intensity of the lumination of each segment of the light emitting device in order to generate a desired mixed color in response to an input control signal.

These further aspects of the invention offer similar advantages as the first discussed aspect of the invention.

These and other aspects of the present invention will now be described in more detail, with reference to the appended drawings showing currently preferred embodiments of the invention.

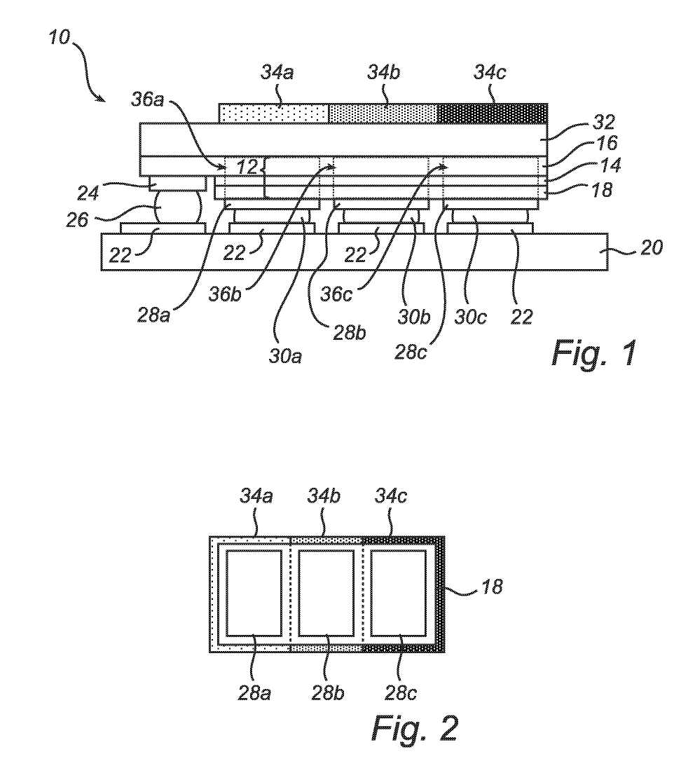

FIG. 1 is a cross-sectional side view of a variable color light emitting device according to an embodiment of the invention,

FIG. 2 is a partial bottom view of the variable color light emitting device in FIG. 1,

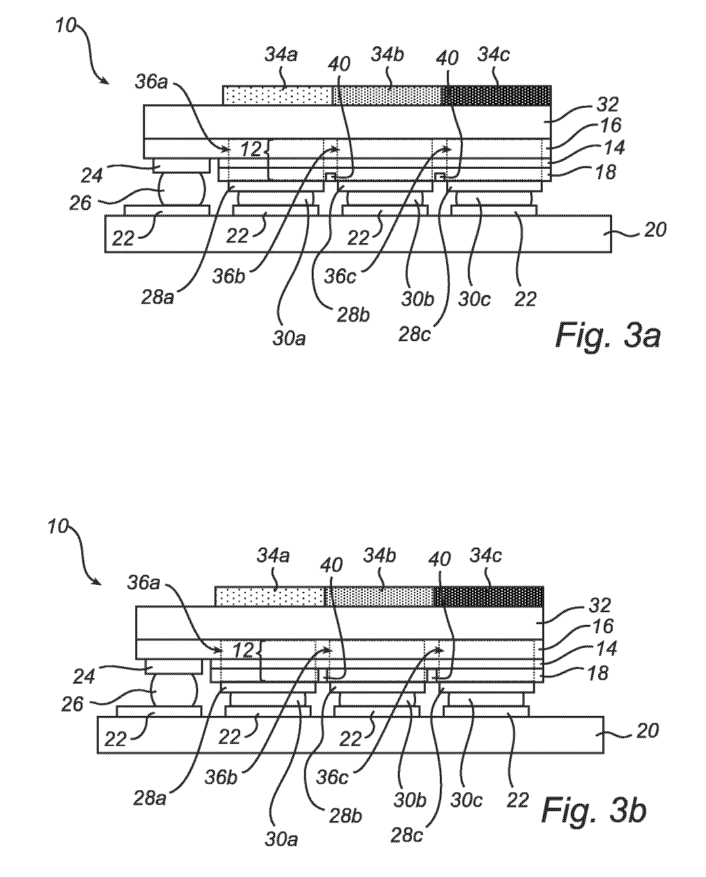

FIGS. 3a-3b are cross-sectional side views of a variable color light emitting device according to another embodiment of the invention,

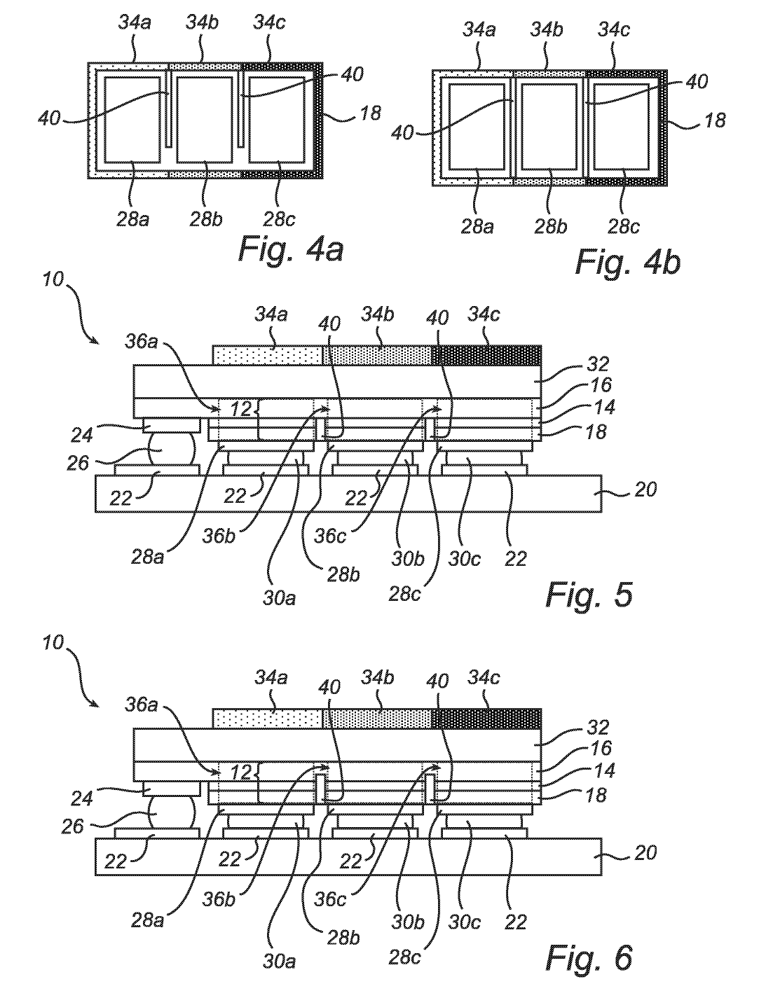

FIGS. 4a-4b are partial bottom views illustrating exemplary high resistance region patterns for the variable color light emitting devices in FIGS. 3a-3b,

FIG. 5 is a cross-sectional side view of a variant of the variable color light emitting devices in FIGS. 3a-3b,

FIG. 6 is a cross-sectional side view of another variant of the variable color light emitting devices in FIGS. 3a-3b,

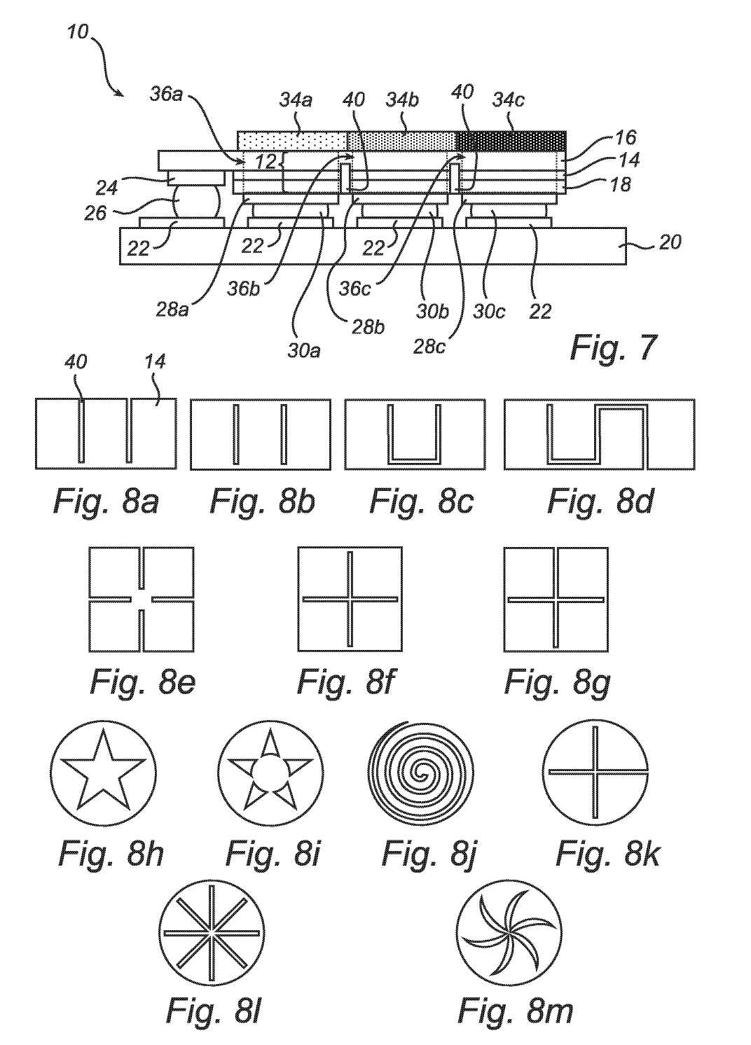

FIG. 7 is a cross-sectional side view of a variable color light emitting device according to yet another embodiment of the invention,

FIGS. 8a-8m are schematic top views illustrating various active layer structures,

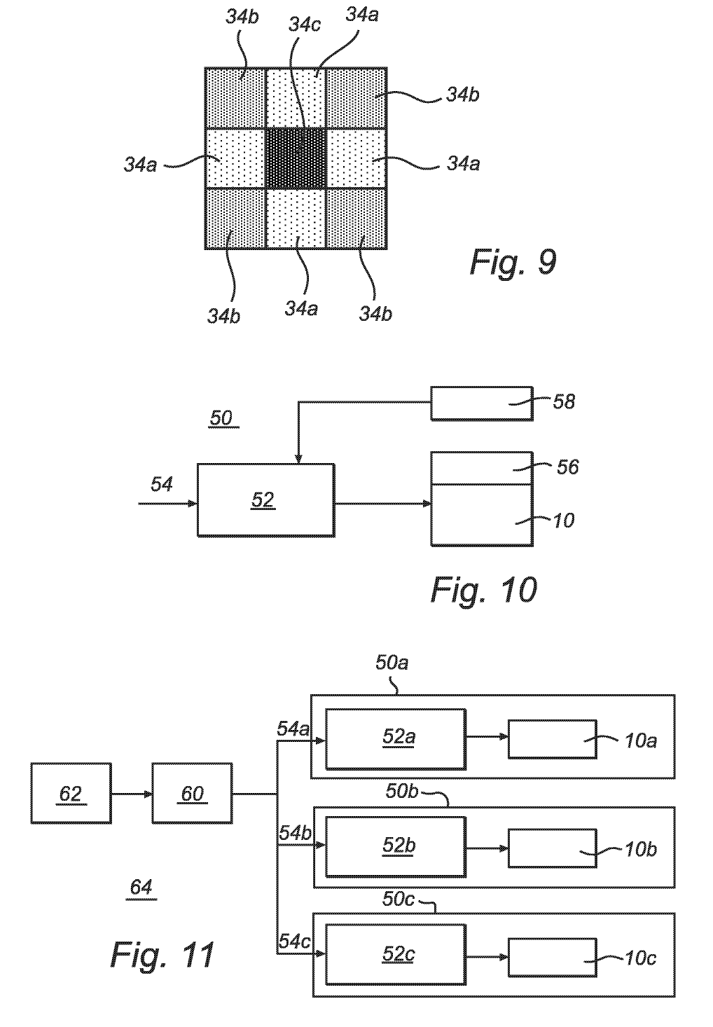

FIG. 9 is a top view of a variable color light emitting device having a 3×3 configuration,

FIG. 10 is a diagram of a variable color lighting system comprising a variable color light emitting device according to the invention, and

FIG. 11 is a diagram of a variable color lighting system network comprising a plurality of variable color light emitting systems of FIG. 10.

FIG. 1 is a cross-sectional side view of a variable color light emitting device 10 according to an embodiment of the invention. The light emitting device 10 comprises a light emitting diode 12, which in turn comprises an active layer 14 interposed between an N-type layer 16 and a P-type layer 18. These layers can for example be appropriately doped GaN layers. The diode 12 is mounted on a submount 20 provided with electrical contacts 22 which are connected to a circuit (not shown) for driving the diode. The N-type layer 16 is provided with a contact 24 which is soldered to one of the electrical contacts 22 (by means of solder bump 26), thereby connecting the N-type layer 16 to the circuit driving the diode. The P-type layer 18 is similarly connected to the circuit via contacts 28a-28c, solder bumps 30a-30c and electrical contacts 22. On top of the N-type layer 16, there is provided a transparent substrate 32, and on top of the transparent substrate 32, there are provided wavelength converters 34a-34c.

FIG. 2 is a partial bottom view of the variable color light emitting device 10 in FIG. 1, and illustrates the P-type layer contacts 28a-28c, the P-type layer 18, and the wavelength converters 34a-34c. Please not that in all bottom view figures, the elements are depicted in a “pyramid” fashion so that for example the top wavelength converters can be shown. However, in actual embodiments, this pyramid structure will not necessarily apply.

Due to the design of the variable color light emitting device 10, the diode 12 is divided into several segments 36a-36c, which segments individually can be actuated in order to emit light. The radiation emitted by the active layer 14 in a segment 36 is converted by its associated wavelength converter 34. Upon operation of the light emitting device 10, depending on the desired overall output, one segment, several segments, or all segments can be ruminating at any given time by addressing the appropriate segment(s). Also, the intensity of the radiation emitted from a certain segment can be controlled. In that way, various colors can be emitted from the same diode.

Assume for example that the wavelength converters 34a-34c correspond to red, green, and blue, respectively. By actuating or addressing segment 36a, red light can be emitted. By addressing segment 36a and 36b, red and green light can be emitted. By addressing all three segments 36a-36c, red, green and blue light can be emitted.

Individually ruminating separate segments or parts of the diode is made possible due to confinement of the current spreading in the diode. The principle behind the confinement of the current spreading in the diode in FIGS. 1 and 2 will be explained in the following.

Current spreading in a particular volume is determined by the volume characteristics (surface area versus depth) and electron/hole mobility. In a semiconductor, the latter is described by diffusion coefficients. For many compound semiconductors, including the AlInGaP and AlInGaN material systems that are the basic materials of visible-light emitting diodes, there is a large difference, often exceeding one order of magnitude, between the electron mobility, relevant in n-type material, and the hole mobility, relevant in p-type material, dependent of the doping levels. When an external electric field is applied over a p-doped semiconductor or n-doped semiconductor (such as the P-type layer 18 or N-type layer 16), the electrical charge current is described by a combination of drift (by virtue of the applied external electric field) and diffusion. For typical doping levels (10¹⁷-10¹⁸ cm⁻³), this results in a strong lateral current spreading in the n-type region, and hardly any of such spreading in the p-type material. Hence, a thick p-doped region is needed to allow sufficient lateral spreading.

In the light emitting device 10 in FIGS. 1 and 2, the thickness of the P-type layer 18 is selected so that the lateral current spreading in the layer, i.e. the current spreading in the horizontal direction in FIG. 1, is limited. In that way, individually addressable segments 36 can be defined by the contact areas between the contacts 28 and the P-type layer 14. Thus, in the embodiment shown in FIGS. 1 and 2, the current spreading is determined by the thickness of the P-type layer 14 and the size and positioning of the contacts 28a-28c. As can be seen in FIGS. 1 and 2, the size of the contacts 28a-28c helps define the segments 36a-36c. Also, the size and positioning of the wavelength converters 34a-24c correspond to the segments 36a-36c.

In the light emitting device 10 in FIGS. 1 and 2, some current spreading may occur between different segments 36. This means that when a first segment is activated, current can spread to a second adjacent segment, so that at least a part of this second segment is ruminating as well. This unwanted current spreading can be decreased by incorporating high-resistance regions in the diode (as illustrated for example in FIGS. 3-6), which high-resistance regions separate/define the segments and block the electrical current in one segment to interact with any neighboring segment.

The light emitting devices in FIGS. 3a-3b are similar to that in FIG. 1, except in that the P-type layer 18 is structured by high-resistance regions 40. In FIG. 3a, the high-resistance regions 40 are incorporated as “filled” grooves in the P-type layer 18. That is, the high-resistance regions 40 extend vertically through part of the cross-section of the P-type layer 18, whereby the P-type layer remains continuous. Alternatively, the high-resistance regions 40 can extend vertically through the whole of the cross-section of the P-type layer 18, up to the active layer 14, as illustrated in FIG. 3b.

Examples of the horizontal or lateral extension of the high-resistance regions 40 in the P-type layer are illustrated in FIGS. 4a-4b. In FIG. 4a, the high-resistance regions extend over almost the entire width of the P-type layer. In FIG. 4b, the high-resistance regions extend over the entire width of the P-type layer. As can be seen in the FIGS. 3a-3b and 4a-4b, the extension of the high-resistance regions 40 thus limits/defines the segments 36. The highly resistive regions 40 can be realized by for example etching, ion plantation, etc.

It should also be noted that combining the variants shown in FIG. 3b and FIG. 4b results in a discontinuous P-type layer. A discontinuous P-layer type provides improved current confinement.

In order to further decrease unwanted current spreading between segments, the high-resistance regions 40 can extend also into the active layer 14, as illustrated in FIG. 5, or still further into the N-type layer 16, as illustrated in FIG. 6. In FIG. 6, the high-resistance region 40 extends vertically through part of the cross-section of the N-type layer 16. The N-type layer 16 remains continuous, in order to avoid that any segment 36 is completely electrically cut-off from the N-type contact 24 and the circuit 22. The high-resistance regions can have the same or different lateral extensions in the layers. For example, the high-resistance regions in the P-type layer can have such extension that the P-type layer becomes discontinuous, while the high-resistance regions in the active layer can have such extension that the active layer remain continuous, i.e. formed in one single piece. Examples of designs of the high-resistance region(s) 40 in the active layer 14, with resulting segments, are illustrated in FIGS. 8a-8m. Each of the FIGS. 8a-8d illustrates a rectangular shaped active layer where at least one high-resistance region extends parallel to the short side of the active layer. Each of the FIGS. 8e-8g illustrates a square shaped active layer where the overall design of the high-resistance region(s) is essentially cross-shaped. Each of the FIGS. 8h-8m illustrates a circular shaped active layer: in FIGS. 8h-8i, the high-resistance region(s) has an overall star-shaped form, in FIG. 8j, the high-resistance region has a spiral-shaped form, and in FIGS. 8k-8m, the high-resistance region has a cross-type-shaped form.

Except for current spreading between segments as discussed above, there may also be optical “cross talk” between pixels. That is, radiation from the active layer, which radiation is emitted through the N-type layer and the transparent substrate to the converters, can be refracted and/or reflected at the interfaces between the various components of the diode. After refraction/reflection, the radiation may reach a wavelength or color converter associated with a neighboring segment. In order to reduce this optical “cross talk”, the relevant components of the diode can be index matched to avoid refraction/reflection. Further, the optical “cross talk” effect can be reduced by removing the transparent substrate between the N-type layer and the converters, so that the converters are in optical and mechanical contact with the diode, as shown in FIG. 7. In FIG. 7, the converters are mounted directly to the N-type layer. It should be noted that the transparent substrate in a similar way can be omitted in any of the light emitting devices shown in FIGS. 1-6.

Also, even though a light emitting device having a 3×1 configuration has been disclosed above (see for example FIG. 2), the light emitting device according to the invention can comprise many more segments, for example nine segments in a 3×3 configuration as shown in FIG. 9. The light emitting device 10 in FIG. 9 comprises one set of one blue converter 34c, one set of four red converters 34a, and one set of four green converters 34b. Correspondingly, the underlying diode is divided into nine addressable segments.

Moreover, several light emitting devices of the type described above can be combined. For example, three 3×1 light emitting devices can be combined to form a 3×3 light emitting device. In this case, segments in different 3×1 light emitting devices can be connected in series. If for instance each 3×1 light emitting device comprises a segment provided with a red color converter, these three “red segments” can be connected in series, forming a red “color channel” which can be powered by a single drive current by means of a single driver. That is, several segments can be addressed in groups. An advantage with using series configuration (instead of individually addressing each segments using parallel connections) is that the voltage is increased rather than the current, which is beneficial for the drivers. Also, using a single connection to several segments reduces the number of required connections.

The variable color light emitting devices disclosed in this application can advantageously be incorporated in a variable color lighting system, an example of which is illustrated in FIG. 10.

FIG. 10 is a diagram of a variable color lighting system 50 comprising a variable color light emitting device 10. The variable color light emitting device 10 can be of any type described above. The light emitting device 10 is coupled to a controller 52. The controller 52 is capable of controlling its associated light emitting device based on an input control signal 54. More specific, the controller 52 is capable of varying the intensity of the radiation from each segment of its associated light emitting device in order to generate a desired mixed color in response to the input control signal.

The variable color lighting system 50 can further comprise various optics 56 adapted to manipulate the output of the light emitting device 10. The optics can for example be beam shaping optics, mixing optics, homogenizing optics, etc.

Also, the variable color lighting system 50 can comprise sensors 58 adapted to measure various characteristics of the light emitting device 10, such as the actual color and flux of the output of the light emitting device, the temperature of the light emitting device, etc. The reason for these measurements is that the optical characteristics of the light emitting devices may change when the they rise in temperature during operation. The measures of the actual output can then be used as feedback values which the controller uses to adjust the light emitting device so that the actual output as much as possible equals the desired output. Thus, the output accuracy of the light emitting device is improved.

Moreover, the variable color lighting system 50 can comprise many additional components, such as active and/or passive cooling elements for keeping the temperature down during operation, voltage and/or current detectors for failure detection, etc.

Several variable color lighting systems 50 can further be coupled together, forming a variable color lighting system network as illustrated in FIG. 11. In FIG. 11, the color variable lighting system network 64 comprises three variable color lighting systems 50a-c, the controllers 52a-c of which are coupled in a network to a central processor 60. The controllers 52a-c can for example be coupled to a common data bus, which in turn is coupled to the central processor 60. Any of a variety of different protocols (such as DMX, DALI, etc.) can be used to transfer data between the central processor 60 and the controllers 52a-c, or amongst the controllers.

The central processor 60 is further coupled to a user interface 62.

Upon operation of the lighting system network 64, a user sets, via the user interface 62, desired color(s), desired flux output(s), lighting patterns, etc. for the lighting system network. The user input is transferred to the central processor 60, which in turn supplies the controllers 52a-c with corresponding input control signals 54a-c. Each controller 52 controls its associated light emitting device 10 according the input control signal, as described above.

The person skilled in the art realizes that the present invention by no means is limited to the preferred embodiments described above. On the contrary, many modifications and variations are possible within the scope of the appended claims. For example, even though the above examples show a flip-chip configuration, it is also possible to use for example a wire bonded diode having contact pads on the top side of the diode.

Further, while FIG. 11 shows a network including three variable color light emitting devices, it should be appreciated that the invention is not limited in this respect, as any number of light emitting devices may be used in the lighting system.

1. A variable color light emitting device (10), comprising a light emitting diode (12) for emitting light, said diode comprising a plurality of electrically conducting layers (14, 16, 18), at least one of which being such that lateral current spreading in the diode is limited to form at least two independently electrically addressable segments (36), for allowing rumination of an optional number of the segments, wherein at least one of the number of segments is provided with a wavelength converter (34) adapted to convert at least part of the light emitted from its associated segment to generate light of a certain primary color.

2. A variable color light emitting device according to claim 1, wherein said diode comprises a single continuous active layer (14) interposed between an N-type layer (16) and a P-type layer (18).

3. A variable color light emitting device according to claim 2, wherein said at least two independently electrically addressable segments share the same single continuous active layer.

4. A variable color light emitting device according to claim 1, wherein said diode comprises at least one high-resistance region (40), the extension of said at least one high-resistance region defining said segments.

5. A variable color light emitting device according to claim 4, wherein said at least one high-resistance region is incorporated in said P-type layer.

6. A variable color light emitting device according to claim 4, wherein said at least one high-resistance region is incorporated in said N-type layer.

7. A variable color light emitting device according to claim 4, wherein said at least one high-resistance region is incorporated in said active layer and at least one of said P-type layer and N-type layer.

8. A variable color light emitting device according to claim 2, wherein electrical contacts (28) are connected to the P-type layer, and wherein the thickness of said P-type layer is such that lateral current spreading in the diode is limited, whereby said segments are defined by the contact area between the contacts and the P-type layer.

9. A variable color light emitting device according to claim 1, wherein said diode is monolithically grown.

10. A variable color light emitting device according to claim 1, wherein the at least one wavelength converter is in mechanical and optical contact with the diode.

11. A variable color lighting system (50), comprising:
at least one variable color light emitting device (10) according to claim 1, and
at least one controller (52), each controller being coupled to at least one variable color light emitting device and capable of varying the intensity of the lumination of each segment of its associated light emitting device(s) in order to generate a desired mixed color in response to an input control signal (54).

12. A variable color lighting system network (64), comprising:
a plurality of variable color light emitting systems (50) according to claim 11, the controllers of which being coupled together in a network, and
a central processor (60) for supplying input control signals, based on instructions from a user interface (62), to the controllers via said network.

13. A variable color light emitting device assembly, comprising a plurality of variable color light emitting devices (10) according to claim 1, wherein the segment responsible of emitting light of a certain primary color in combination with any wavelength converter in one of the light emitting devices is connected in series with the segment or segments responsible of emitting light of the same primary color in at least one other of the light emitting devices.

14. A controller (52) for a variable color lighting system, the system comprising at least one variable color light emitting device (10) according to claim 1, wherein the controller is coupled to at least one of the variable color light emitting devices and adapted to vary the intensity of the lumination of each segment of its associated light emitting device(s) in order to generate a desired mixed color in response to an input control signal (54).

15. A method for controlling a variable color light emitting device (10) according to claim 1, the method comprising:
varying the intensity of the lumination of each segment of the light emitting device in order to generate a desired mixed color in response to an input control signal (54).
